(19) United States
(12) Patent Application Publication
(10) Pub. No.: US 2004/0046246 A1
(43) Pub. Date: Mar. 11, 2004

(54) Press-fit package diode

(75) Inventors: Chien-Ming Cheng, Yilan Hsien (TW); Ting-Pu Chen, Yilan Hsien (TW)

Correspondence Address: SENNIGER POWERS LEAVITT AND ROEDEL, ONE METROPOLITAN SQUARE, 16TH FLOOR, ST LOUIS, MO, 63102, US

(73) Assignee: Yenyo Technology Co., Ltd.

(21) Appl. No.: 10/657,875

(22) Filed: Sep. 9, 2003

(30) Foreign Application Priority Data
Jan. 21, 2002 (TW) 091200505

(51) Int. Cl. H01L 23/10; H01L 23/34

(52) U.S. Cl. 257/706

(57) ABSTRACT

The invention related to a diode 2 comprising a connecting means (6) and a heat sink base (7). Said connecting (6) has a flat end (5) fixed on a die 16 and another end without fix shape. Said heat sink base (7) comprises: a base (18) which is at the bottom of said heat sink base (7); a press-fit region (4) which is set around said base (18); a solder platform (17) which is set above said base (18); a die (16) which has a first side and a second side electrically coupled to said flat-end (5) and said solder platform (17), respectively, and is fixed on said solder platform (17); a shoulder (12) which is extended acclivitously from said solder platform (17), the root of said shoulder connected to said solder platform 17 having a kink; and a cup (14) which is extended upwardly from periphery of said base (18).

### FIELD OF INVENTION

The invention relates to an improved press-fit package semiconductor, in particular, to an improved press-fit package diode.

### BACKGROUND OF THE INVENTION AND RELATED ART

In the electronic-related industrial applications, especially in the mobile industrial application, it is required to use components that have the best heat transfer ability. Thus, there are many improved inventions of diodes using such a press-fit package. The prior art references are listed related as follows:

1. ROC Patent Publication No. 419,758;

2. U.S. Pat. No. 6,060,776;

3. PCT Patent Publication No. WO 95/15578.

The objects of the prior art are to let the diode have better heat transfer ability and resistance against pressure. But the structures of the prior art have their respective unavoidable disadvantages that reduce the industrial applicability. The structures disclosed in the present invention can avoid these disadvantages and greatly improve the industrial applicability.

The Disadvantages of the Prior Arts:

ROC Patent Publication No. 419,758 (please refer to FIG. 1);

1. During the etching process, since the shoulder 12 is taller than the die 16, it hinders the circulation of the etching solution, deteriorates the etching quality and make the cleaning of harder to do.

2. The solder plate 17 on which the die 16 is set has no kink (please refer to FIG. 6A). Thus the path of preventing the moisture is shorter and the diode 2 is easier to be damaged.

U.S. Pat. No. 6,060,776 (please refer to FIG. 2);

1. When the etching process is done, it is harder to proceed the passivate process on the interface. In other words, it is harder to fix the passivative material 10 around the die 16 because it has to be done horizontally.

2. Besides, the shoulder 12 is shorter than the die 16. Since the expansion coefficient is larger than the copper housing, the expansion of the epoxy 8 generates pressure on the die 16 and can damage the die 16 when it suffers heat, or generates a gap that allows the moisture to enter and damage the diode 2.

PCT Patent Publication No. WO 95/15578 (please refer to FIG. 3);

1. The shoulder 12 is shorter than the die 16. The epoxy 8 generates pressure on the die 16 and can damage the die 16 when it suffers heat, or generates a gap which allows the moisture to enter and damage the diode 2.

2. The solder plate 17 on which the die 16 is set has no kink (please refer to FIG. 6A). Thus the path of preventing to moisture is shorter and the diode 2 is easier to be damaged.

### SUMMARY OF THE INVENTION

The present invention can surmount the disadvantages of the prior art and achieve the following objects:

1. To improve the yield (since it is easier to etch and to clean, the yield will be improved relatively);

2. To reduce the production cost (since the yield is improved, the cost will be reduced relatively);

3. To improve the resistance against the pressure and the moisture of the products and to extend the life cycle (since the path of preventing the moisture is longer, the diode 2 will be harder to be damaged).

### BRIEF DESCRIPTION OF THE DRAWINGS

The technical contents and features of the present invention will be easier understood with reference to the comparison among the accompanying drawings (FIGS. 4, 5 and 6) of the preferred embodiments and the accompany drawings (FIGS. 1, 2 and 3) of the prior art references in which:

FIG. 1 represents the prior art reference ROC Patent Publication No. 419,758;

FIG. 2 represents the prior art reference U.S. Pat. No. 6,060,776;

FIG. 3 represents the prior art reference PCT Patent Publication No. WO 95/15578;

FIG. 4 is the cross-sectional diagram of the preferred embodiment of the present invention, wherein the protective sheath 20 is in the inner side of the cup 14;

FIG. 5 is the cross-sectional diagram of the preferred embodiment of the present invention, wherein the protective sheath 20 is in the outer side of the cup 14;

FIG. 6 is the cross-sectional diagram of the heat sink base 7 of the diode of present invention;

FIG. 6A is the partial enlargement of the cross-sectional diagram of the heat sink base 7 of the diode of the present invention.

### DETAILED DESCRIPTION OF THE PREFERRED EMBODYMENT

A preferred embodiment of the present invention is described below with reference to the accompanying drawings. The same element in the drawings is represented by the same reference numeral.

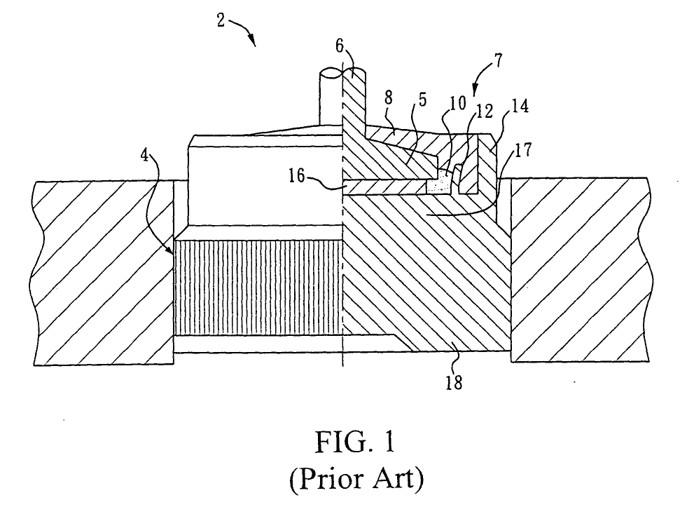

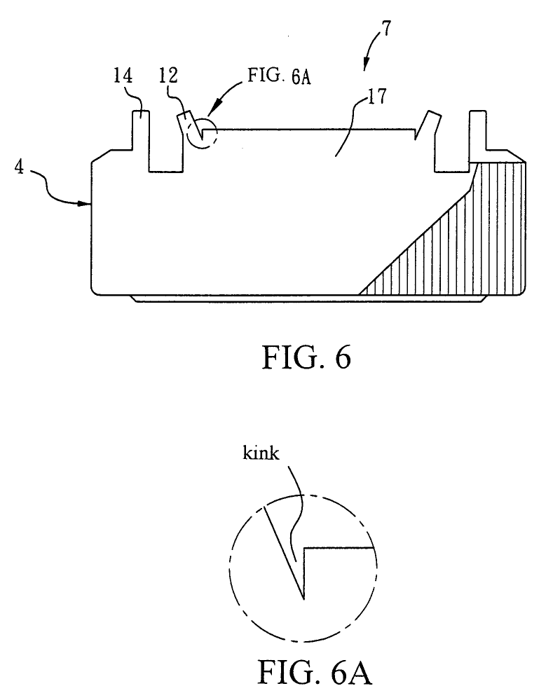

FIG. 1 represents the prior art ROC Patent Publication No. 419,758. The advantage is that since the shoulder 12 is taller than the die 16, the shoulder 12 will protect the die 16 from being pressed by the expansion of the epoxy 8 when the epoxy 8 suffers the heat. But the disadvantages are that: (1) during the etching process, since the shoulder 12 is taller than the die 16, it hinders the circulation of the etching solution, deteriorates the etching quality and makes the cleaning harder to do; (2) since the solder plate 17 on which the die 16 is set has no kink (please refer to FIG. 6A), the path of preventing the moisture is shorter and the diode 2 is easier to be damaged.

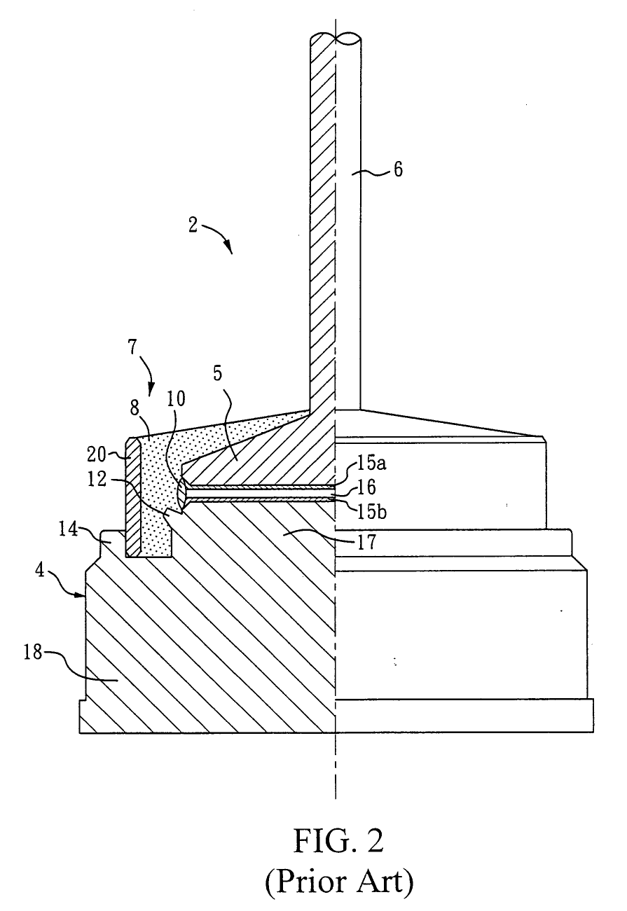

FIG. 2 represents the prior art U.S. Pat. No. 6,060,776. The advantage is that since the shoulder 12 is shorter than the die 16, the shoulder 12 would not hinder the etching solution from circulation and thus achieve a more complete and uniform etching in the process of etching the diode 2. Also it is easier to clean, thus the yield is improved and the average cost is reduced. However, the disadvantages are that: (1) when the etching process is done, it is harder to fix on the interface. In other words, it is harder to fix the passivative material 10 around the die 16 because it has to be done horizontally; (2) besides, the shoulder 12 is shorter than the die 16. Since the expansion coefficient is larger than the copper housing, the expansion of the epoxy 8 generates pressure on the die 16 and can damage the die 16 when it suffers heat, or generates a gap that allows the moisture to enter and damage the diode 2.

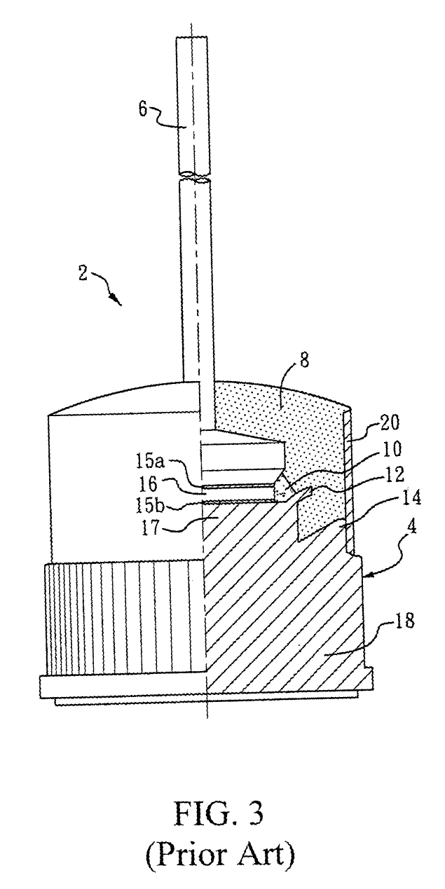

FIG. 3 represents the prior art reference PCT Patent Publication No. WO 95/15578. The advantage is that since the shoulder 12 is slightly shorter than the die 16, the shoulder 12 would not hinder the etching solution from circulation and thus achieve a more complete and uniform etching in the process of etching the diode 2. Also it is easier to clean, thus the yield is improved and the average cost is reduced. However, the disadvantages are that: (1) the shoulder 12 is slightly shorter than the die 16. Since the expansion coefficient is larger than the copper housing, the expansion of the epoxy 8 generates pressure on the die 16 and can damage the die 16 when it suffers heat, or generates a gap that allows the moisture to enter and damage the diode 2; (2) since the solder plate 17 on which the die 16 is set has no kink (please refer to FIG. 6A), the path of preventing the moisture is shorter and the diode 2 is easier to be damaged.

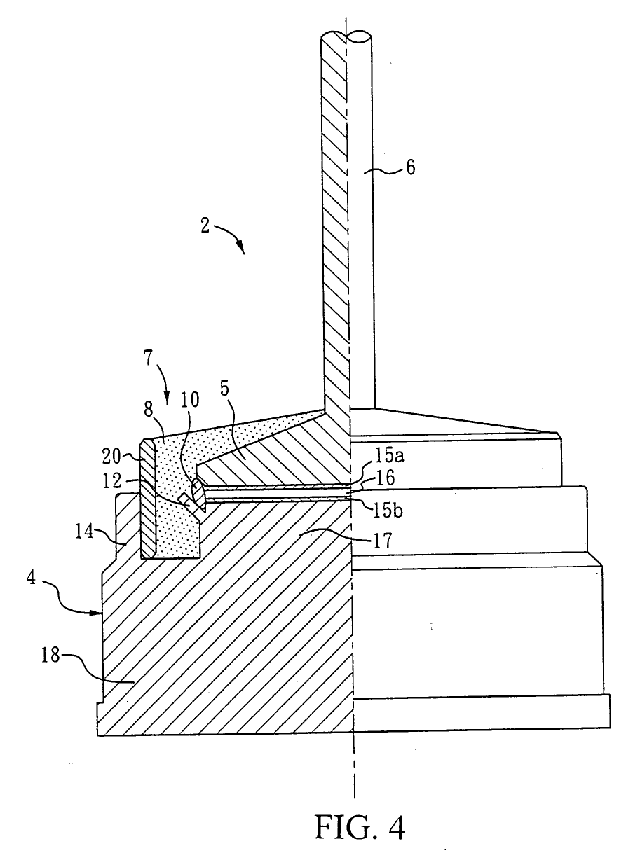

FIG. 4 is the cross-sectional diagram of the structure of the preferred embodiment of the diode 2 of the present invention; said diode 2 comprises 2 major parts: a connecting means 6 and a heat sink base 7; one end of said connecting means 6 is a flat end 5 fixed on a die 16 and the other end has no fix shape (not shown); said heat sink base 7 comprises: a base 18 which is at the bottom of said heat sink base 7; a press-fit region 4 which is around said base 18; a solder platform 17 which is located above said base 18; a die 16 which has a first side and a second side electrically coupled to said flat-end 5 and said solder platform 17, respectively, and is fixed on said solder platform 17; a shoulder 12 which is extended from said solder platform 17, the root of said shoulder connected to said solder platform 17 has a kink; and a cup 14 which is extended upwardly from periphery of said base 18. A protective sheath 20 can be formed after the etching process and the passivant process are finished to protect said heat sink base 7.

The present invention surmounts the disadvantages of the prior art and has the following advantages: (1) The etching of the diode 2 is more completely and evenly in the etching process and is easier to clean, thus improving the yield and reducing the cost. This is achieved by adjusting the height of the shoulder 12 to be substantially the same as the die 16. When the height of the shoulder 12 is substantially the same as the die 16, the shoulder 12 would not hinder the circulation of the etching solution. Thus, a more completely and evenly etching can be achieved. (2) It is easier for the passivant process on the interface portion, in other words, the passivant process of fixing the passivative material 10 (for example, polyimide, silicon rubber, silicone gel, etc.) is easier to proceed. This is achieved by the acclivitous shoulder 12. Since the passivative material 10 can be supported and fixed by the shoulder 12 in the passivant process, the passivant process becomes easier. (3) The present invention can absorb the stress directed to the die 16 generated by the expansion under heat.

This can also be achieved by the acclivitous shoulder 12. Said shoulder 12 can absorb the stress directed to the die 16 generated by the expansion of the epoxy 8 under heat, so as to prevent the die 16 from being damaged and to avoid the generation of the crack. (4) The present invention can extend the path of the moisture to the die 16, so as to improve the ability of the die 2 against the moisture and to extend the lifecycle of the die 2. Since the kink exists as shown in FIG. 6A, the moisture can not reach the die 16 directly even if it enters the crack between the shoulder 12 and the passivative material 10. Thus, the ability of the diode 2 against the moisture is better and the lifecycle of the diode is extended.

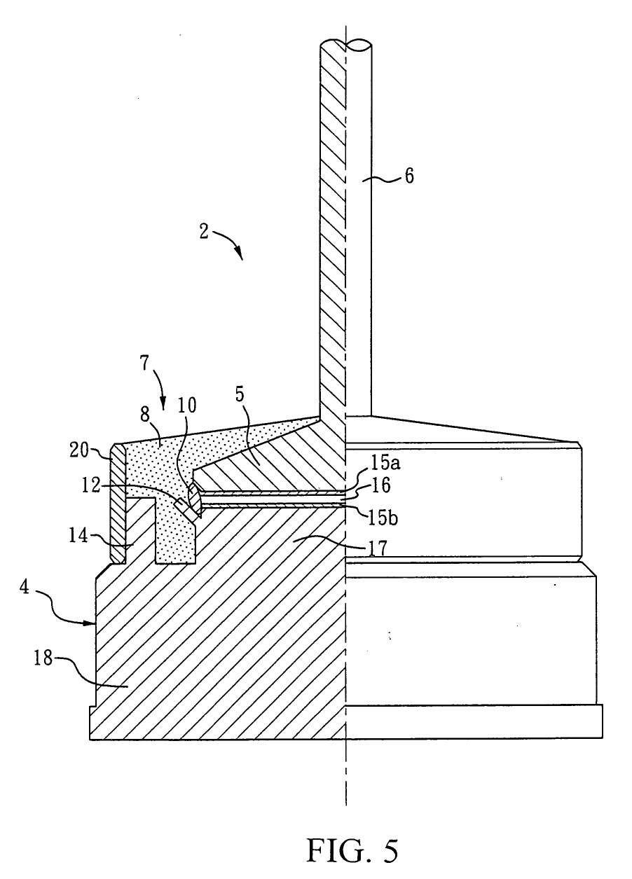

FIG. 5 is the cross-sectional diagram of an alternative embodiment of the diode 2 of the present invention. The only difference between FIG. 4 and FIG. 5 is that the protective sheath 20 is formed outside the cup 14 so as to protect the cup 14.

FIG. 6 is the cross-sectional diagram of the heat sink base 7 of a diode 2 according to the present invention. It indicates that the height of the cup 14 and the shoulder are substantially the same. The height of the cup 14 can also be higher or lower than the shoulder 12 (not shown). FIG. 6 also indicates the position of the kink.

FIG. 6A is the partial enlargement of the cross-sectional diagram of the heat sink base 7 of a diode 2 according to the present invention. It indicates the partial enlargement of the position where the kink exists. Even if the moisture enters the crack between the shoulder 12 and the passivative material 10, it can not reach the die 16 directly. Thus, the ability of the diode 2 against the moisture is better and the lifecycle of the diode is extended.

With the above descriptions, it is obvious that the embodiments and description are not indeed to limit the invention. The invention may be varied in many ways. Such variations are not to be regarded as a departure from the spirit and scope of the invention, and all such modifications as would be obvious to one skilled in the art are intended for inclusion within the scope of the following claims.

1. A diode 2 comprising a connecting means 6 and a heat sink base 7;
said connecting means 6 comprising a flat end 5 fixed at a die 16 and the other end having no fixed shape;
said heat sink base 7 comprising;
a base 18 which is on the bottom of the heat sink base 7;
a press-fit region 4 which is around said base 18;
a solder platform which is above said base 18;
a die 16 which has a first side and a second side electrically coupled to said flat end 5 and said solder platform 17, respectively;
a shoulder 12 which is extended acclivitously from said solder platform 17, the root of said shoulder 12 connected to said solder platform 17 having a kink; and
a cup 14 which is extended upwardly from the periphery of said base 18.

2. The diode 2 of claim 1, wherein said shoulder 12 has a height which is substantially the same as said die 16.

3. The diode 2 of claim 1, wherein said connecting means 6 is a lead wire.

4. The diode 2 of claim 1, further comprises two solder layers 15a and 15b which sandwich said die 16 above and under, respectively.

5. The diode 2 of claim 4, further comprises passivative material 10 used to surround said wafer 16.

6. The diode 2 of claim 5, further comprises an epoxy 8 for surrounding outside said passivative material 10.

7. The diode 2 of claim 6, further comprises a protective sheath 20 for surrounding said epoxy 8 inside said cup 14.

8. The diode 2 of claim 6, further comprises a protective sheath 20 for surrounding said epoxy 8 outside said cup 14.
